(19) United States
(12) Patent Application Publication
(10) Pub. No.: US 2015/0179583 A1
(43) Pub. Date: Jun. 25, 2015

(54) SEMICONDUCTOR DEVICES COMPRISING EDGE DOPED GRAPHENE AND METHODS OF MAKING THE SAME

(71) Applicant: Harper Laboratories, LLC, Huntsville, AL (US)

(72) Inventors: Kevin BRENNER, Atlanta, GA (US); Romeil SANDHU, Huntsville, AL (US)

(21) Appl. No.: 14/620,771

(22) Filed: Feb. 12, 2015

Related U.S. Application Data
(62) Division of application No. 14/135,882, filed on Dec. 20, 2013.
(60) Provisional application No. 61/844,040, filed on Jul. 9, 2013.

(51) Int. Cl. H01L 23/532; H01L 21/768; H01L 21/3213; H01L 23/528

(52) U.S. Cl. CPC H01L 23/53276; H01L 23/528; H01L 21/76838; H01L 21/32136

(57) ABSTRACT

A method of forming an edge-doped graphene channel is described. The method involves selectively removing graphene from a graphene layer on a substrate in the presence of a dopant to form graphene channels. The dopant forms bonds with carbon atoms on the edge of the graphene such that the graphene channels are edge doped. An article of manufacture is also provided which includes a substrate layer, one or more edge-doped graphene channels on the substrate layer and a layer of an etch mask material on and coextensive with the one or more graphene channels. An article of manufacture is also provided which includes a substrate layer and one or more edge-doped graphene channels on the substrate layer, wherein each of the one or more the graphene channels has a width less than 100 nm and a carrier density greater than 5×10¹² cm⁻³.

### CROSS REFERENCE TO RELATED APPLICATIONS

This application is a divisional of U.S. patent application Ser. No. 14/135,882, filed on Dec. 20, 2013, pending, which claims the benefit of Provisional U.S. Application Ser. No. 61/844,040, filed Jul. 9, 2013, expired. Each of the above-referenced applications is incorporated by reference herein in its entirety.

### BACKGROUND

1. Field

This application relates generally to a semiconductor structure and to methods of forming the same and, in particular, to edge-doped graphene channels and to methods of making the same. The edge doped graphene can be used to form interconnects for a semiconductor device.

2. Background of the Technology

The ability to tune the carrier density of a semiconductor or semimetal is important in the manufacture of semiconductor chips. Moreover, the carrier density can be adjusted to increase the electrical conductivity of channels or to form p-type and n-type regions of a semiconductor material. The carrier density of a material is commonly adjusted using two different methods: (1) electrostatic doping with a gate or (2) chemical doping. Chemical doping is advantageous for applications such as interconnects since it does not require added fabrication of a gate structure or static power dissipation to tune to the carrier density.

There is an increased demand in the industry for smaller and faster transistors used to provide the core functionality of the integrated circuits used in semiconductor devices. To achieve higher densities, there has been, and continues to be, efforts toward down scaling the dimensions of the devices on semiconductor wafers. These trends are pushing the current technology to its limits. In order to accomplish these trends, high densities, smaller feature sizes, smaller separations between features, and more precise feature shapes are required in integrated circuits (ICs).

Nanoscale copper (Cu) interconnects that make electrical connections to active devices, mainly transistors, are an essential component of nearly all semiconductor chips. In Complementary Metal Oxide Semiconductor (CMOS) chips, this Cu interconnect fabric is applied as a separate component to the transistors that are embedded in the Si wafer. As the dimensions of these transistors are continually scaled down to improve performance, commonly captured through Moore's Law, the Cu interconnect fabric must also be scaled. Whereas transistors improve performance with scaling, the electrical resistance of Cu interconnects rapidly increases when scaled due to intrinsic properties of the metal. As a result, Cu interconnects are expected to become a crippling bottleneck to CMOS chip performance in the coming technology nodes. Moreover, the underlying mechanisms that produce this increasing resistance, grain-boundary and sidewall scattering, are intrinsic to nanoscale Cu and cannot be overcome through novel redesigns of the interconnects. Just as the CMOS industry transitioned from Al to Cu interconnects circa 1997, the spotlight is now focused on replacement materials for Cu. Edge doped graphene interconnects can potentially replace local Cu interconnects in an on-chip environment.

Graphene is essentially a flat sheet of carbon atoms. A graphene sheet is a 2 dimensional conducting lattice. Traditional chemical doping techniques for three-dimensional (3D) semiconductors or semimetals involves the physical embedding of dopant atoms within the bulk of the material (e.g., diffusion or ion implantation). Embedding the dopant species within the center of the graphene lattice, as with traditional 3D chemical doping, is problematic as these species degrade the electrical conductivity by scattering mobile charge. In addition, chemical doping by coating the surface of the graphene with a film that tunes the carrier density using charge transfer is problematic as it is only capable of weak carrier densities, and may still degrade the electrical conductivity. As materials begin to approach 2D and 1D dimensions, different methods of chemical doping that depart from traditional techniques used for 3D materials are required.

Accordingly, there exists a need for improved methods of forming doped graphene structures for semiconductor applications.

### SUMMARY

A method of forming an edge-doped graphene channel is provided which comprises:

forming one or more graphene channels having edges by selectively removing graphene from a graphene layer, wherein the graphene layer is on a substrate and wherein formation of the graphene channels occurs in the presence of a dopant;

wherein atoms of the dopant form bonds with carbon atoms on the edge of the graphene such that the one or more graphene channels are edge doped.

A method of forming an edge-doped graphene channel is also provided which comprises:

forming one or more graphene channels having edges by selectively removing graphene from a graphene layer, wherein the graphene layer is on a substrate; and

exposing the graphene to a dopant during and/or after formation of the one or more channels;

wherein atoms of the dopant form bonds with carbon atoms on the edge of the graphene such that the one or more graphene channels are edge doped; and

wherein the channels have a width less than 100 nm and a carrier density greater than 5×10¹² cm⁻³

An article of manufacture is also provided which comprises:

a substrate layer;

one or more graphene channels on the substrate layer, wherein the graphene channels have edges and wherein atoms of a dopant form bonds with carbon atoms on the edges of the graphene channels; and

a layer of an etch mask material on and coextensive with the one or more graphene channels.

An article of manufacture is also provided which comprises:

a substrate layer;

one or more graphene channels on the substrate layer, wherein the graphene channels have edges and wherein atoms of a dopant form bonds with carbon atoms on the edges of the graphene channels;

wherein each of the one or more the graphene channels has a width less than 1 μm and a carrier density greater than 10¹³ cm⁻³.

These and other features of the present teachings are set forth herein.

### BRIEF DESCRIPTION OF THE DRAWINGS

The skilled artisan will understand that the drawings, described below, are for illustration purposes only. The drawings are not intended to limit the scope of the present teachings in any way.

FIGS. 1A and 1B are schematics showing the side view and the top view, respectively, of a starting material for making a graphene channel comprising a graphene layer on a dielectric layer.

FIGS. 2A and 2B are schematics showing an etch mask on the graphene layer to define the graphene channel.

FIGS. 3A and 3B are schematics showing edge doping applied in the same process step as the channel is etched.

FIGS. 4A and 4B are schematics showing the graphene channel on the dielectric layer after the etch mask is removed.

FIG. 4C is a schematic showing the edge doped graphene sheet wherein the dopant species is shown bonded along the edge of the graphene lattice.

FIG. 5A is an optical image of a monolayer of graphene.

FIG. 5B is an optical image of four-point contact metallization patterned using Electron Beam Lithography (EBL) on a graphene monolayer.

FIG. 5C is an optical image of a Ti/Au metal stack deposited using an electron beam evaporator followed by a standard liftoff process.

FIG. 5D is an optical image of graphene channels patterned using electron beam lithography (EBL) and the negative tone resist HSQ.

FIG. 6 is a graph showing carrier density as a function of graphene interconnect width for four different batches of graphene interconnects.

FIG. 7A is an SEM image of a graphene sheet edge doped in a plasma chamber using a plasma of the doping specie wherein the graphene sheet was made using exfoliated graphene.

FIG. 7B is an SEM image of a graphene sheet edge doped in a plasma chamber using a plasma of the doping specie wherein the graphene sheet was made using epitaxial graphene.

FIG. 7C is an SEM image of a graphene sheet that was edge doped by mechanical exfoliation in a glovebox purged with the dopant specie.

FIG. 8 is a an SEM image of a graphene interconnect that was edge doped after patterning.

FIGS. 9A and 9B are graphs showing the scaling trends associated with edge doped graphene sheets.

FIG. 10 is a bar chart showing resistivity as a function of width (nm) for copper and edge-doped graphene interconnects.

FIG. 11 is a graph of conductance as a function of gate voltage for p-type edge doped and n-type edge-doped graphene.

FIG. 12 which is a graph showing that C-atoms in the graphene sheet along the edge are orders of magnitude more efficient for chemical doping than C-atoms in the surface/basal plane of the material.

FIG. 13 is an SEM image of a nanoscale (20 nm width) graphene interconnect with edge doping applied during the plasma etch.

FIG. 14 is a schematic showing an edge doping recipe implemented on an ICP tool.

FIG. 15 is a graph of carrier density versus width for graphene interconnects.

FIG. 16 is a plot of resistivity as a function of interconnect width for three different interconnects: Cu, edge doped graphene, and basal doped graphene.

FIG. 17 is a graph showing resistance as a function of carrier concentration for graphene interconnects having different backscattering probability (P) values and a linewidth of 7.5 nm.

FIG. 18 is a graph of delay as a function of carrier concentration for graphene interconnects having different backscattering probability (P) values and a linewidth of 7.5 nm.

FIG. 19 is a graph of energy delay product (EDP) as a function of carrier concentration for graphene interconnects having different backscattering probability (P) values and a linewidth of 7.5 nm.

### DESCRIPTION OF THE VARIOUS EMBODIMENTS

A semiconductor device comprising a graphene electrical channel with chemical doping applied to the edge of the crystal lattice is provided. The edge doping of the graphene channel can result from the chemical passivation of dangling σ-bonds along the edge of the etched or cleaved graphene. Exemplary and non-limiting embodiments of the doping specie include Nitrogen, Oxygen, and Hydrogen.

According to some embodiments, the dopant specie can be present at the moment that the graphene edge is formed. While not wishing to be bound by theory, it is believed that the presence of the dopant specie during edge formation prevents C—C reconstruction at the graphene edge. This could be a result of the fact that passivation by the dopant specie provides an energetically favorable alternative to C—C reconstructions at the graphene edge. Edge doping can be applied by etching the graphene into the channel using energetic plasma of the dopant specie, such as using a nitrogen plasma to etch the graphene thereby forming an N-doped graphene channel. According to some embodiments, the graphene can be cleaved in an environment rich with the dopant specie to form a graphene channel edge doped with the dopant specie.

The present invention is in the technical field of nanoscale graphene electronic devices. More specifically, the present invention can be used to tune the carrier density in nanoscale graphene channels for applications such as interconnects. The carrier density can be tuned to increase the electrical conductivity of the channel or to pattern p-type and/or n-type regions in the graphene.

The ability to tune the carrier density in a semiconductor or semimetal is essential to the formation of semiconductor chips. The carrier density can be used to increase the electrical conductivity of channels or to form p-type and n-type regions. The carrier density of a material is commonly tuned through two methods: (1) electrostatic doping with a gate or (2) chemical doping. Chemical doping is advantageous for applications such as interconnects as it does not require added fabrication of a gate structure or static power dissipation to tune to the carrier density.

According to some embodiments, a graphene channel is chemically doped through passivation of the lattice edge with dopant species. At the moment the graphene lattice is physically broken to pattern a device structure, the highly reactive dangling σ-bonds will undergo C—C reconstructions that render the edge un-doped and chemically inert. Passivation of the lattice edge is favored if the dopant specie is physically present at the edge at the moment that the edge is formed and the dopant specie provides an energetically favorable alternative to C—C lattice reconstructions. According to some embodiments, edge passivation is accomplished by cleavage of the graphene in an environment that is rich with or purged with the dopant specie, such as a glove box. According to some embodiments, edge passivation is accomplished by using an energetic plasma of the dopant specie to etch the graphene, such as by the use of an Inductively Coupled Plasma (ICP) tool. Non-limiting examples of the dopant species include Nitrogen, Oxygen, and Hydrogen.

One non-limiting application of edge doped graphene is local on-chip interconnects. Edge doped graphene interconnects can potentially replace local Cu interconnects in an on-chip environment.

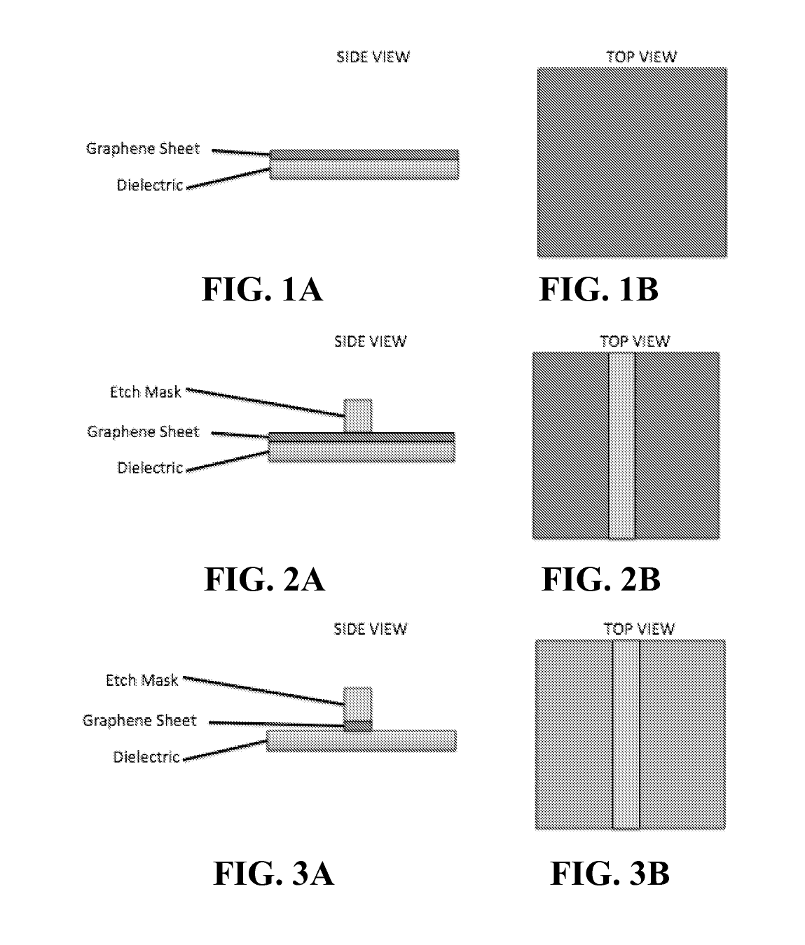

A method of forming an edge doped graphene channel is illustrated in FIGS. 1-4. As shown in FIGS. 1A and 1B, the starting material is a graphene sheet supported by a SiO₂ dielectric. As shown in FIGS. 2A and 2B, an etch mask is patterned on the graphene sheet. The nanoscale graphene channel can be defined by using a negative-tone etch mask. The negative tone etch mask can be developed via electron-beam or optical lithography. Referring to FIGS. 3A and 3B, the channel is shown etched into the graphene sheet. The graphene can be etched, for example, using an inductively coupled plasma (ICP) etch tool. A low-power nitrogen plasma (N-plasma) can be used to etch the graphene. The N-plasma used to etch the graphene can be as dense as possible and can consist only of N. After etching, the power can be reduced to cut off the plasma while still purging Nitrogen gas into the chamber (e.g., for an additional minute). The chamber can then be vented and the graphene channel removed.

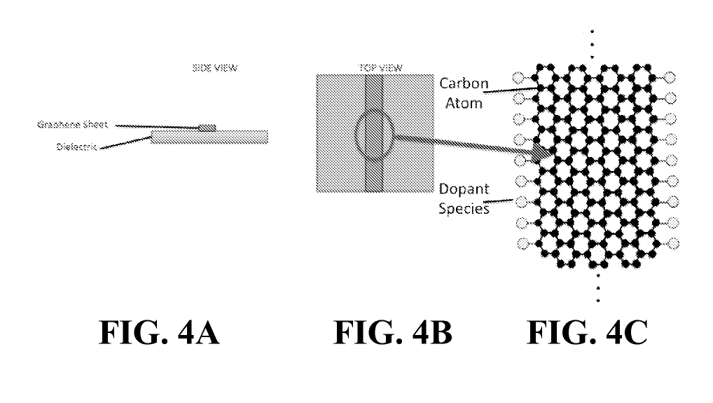

The etch mask can then be optionally removed. FIGS. 4A and 4B are schematics showing the graphene channel on the dielectric layer after the etch mask is removed. FIG. 4C is a schematic showing the edge doped graphene sheet wherein the dopant species is shown bonded along the edge of the hexagonal graphene lattice. As shown in FIG. 4C, the dopant specie forms sigma bonds with C atoms at the graphene edge.

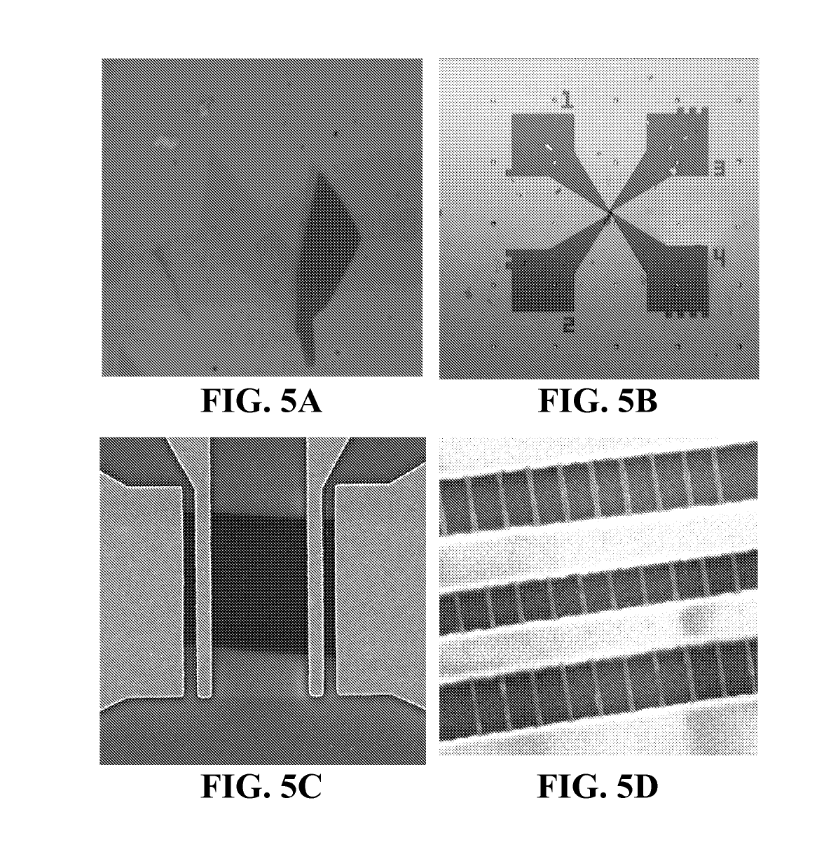

Images of a process flow that can be used to fabricate an edge doped graphene channel are shown in FIGS. 5A-5D and described below. The graphene channel can be fabricated using exfoliated or CVD graphene sheets as a starting material.

Mechanically exfoliated graphene sheets were applied to an oxidized (90 nm SiO₂) Si wafer. The graphene sheets used were mechanically exfoliated from Grade A Kish graphite and were supplied by Toshiba Ceramic Company. Monolayer graphene was identified using optical contrast. These exfoliated graphene sheets were verified using Raman Spectroscopy and Atomic Force Microscopy (AFM). Optical imagery of the monolayer graphene is shown in FIG. 5A. Although a mechanically exfoliated graphene sheet is depicted, a chemical vapor deposition (CVD) graphene sheet could also be used.

A four-point contact metallization was then patterned using Electron Beam Lithography (EBL). A four-point structure was used to remove contact resistance from the measurements and ensure that the testing accurately monitors the performance of the interconnect. Patterning was done using the positive tone resist ZEP520A followed by development in n-Amyl Acetate. The structure post-development is shown in FIG. 5B.

Once patterned, a Ti/Au metal stack was deposited using an Electron Beam Evaporator followed by a standard liftoff process. The fabricated structure prior to the application of chemical doping is shown in FIG. 5C.

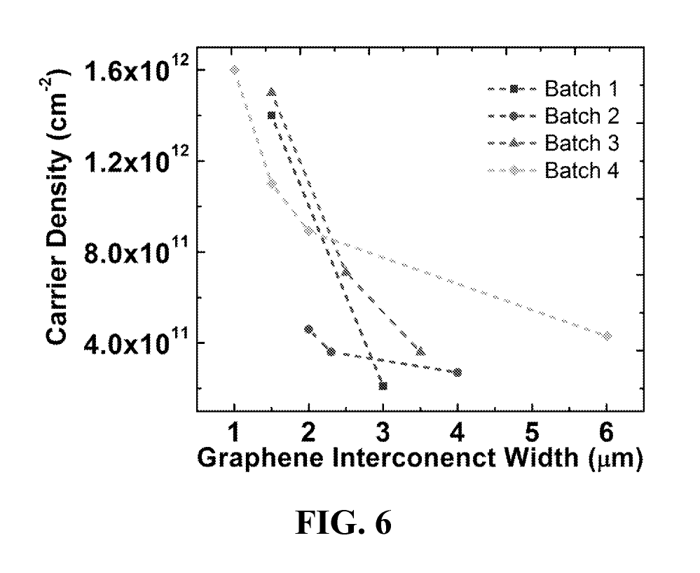

As graphene channels are scaled below 50 nm, they are subject to reductions in mobility as a result of scaling. Unlike Cu, these line-edge-roughness (LER) reductions in mobility (μ) are process-dependent and can be overcome by increasing the carrier density (n). It has been shown that by passivating the edge of graphene channels with the proper selection of elements (e.g., nitrogen), ultrahigh values for carrier density can be induced to push the resistivity (ρ) of graphene below that of Cu. Specifically, it has been experimentally demonstrated that nearly every passivated atom along the edge of the interconnect can contribute ˜1 free carrier for conduction. As a result, “edge doped” graphene channels exhibit a scaling trend of increased carrier density and reduced resistance as the channel width shrinks—this is opposite to Cu whose p increases with scaling. These trends are shown in FIG. 6. Furthermore, it has been shown that N-passivated edges are energetically favorable to un-passivated edges, thus having N available as the interconnect is formed is an optimal route for edge doping the interconnect.

The interconnects were etched using a dense N-plasma etch to achieve simultaneous etching and edge doping. Plasma etching is particularly attractive as such tools are readily available in existing CMOS infrastructure. Lastly, carrier density values have been extrapolated to smaller channel widths for edge doped graphene channels. Based on the extrapolated values, edge doped graphene channels having channel widths in the range of 5 nm to 100 nm should be sufficient to outperform Cu. According to some embodiments, edge doped graphene channels having channel widths of 10 nm-50 nm are provided.

The graphene channels can be patterned using electron beam lithography (EBL) and the negative tone resist Hydrogen Silsequioxane (HSQ). Although EBL is used, this patterning could be easily accomplished using state of the art photolithographic techniques in commercial fabs. The patterned graphene channels (set of 10) between the metal contacts are shown in FIG. 5D. Graphene channels have been patterned having widths of 8-50 nm.

The final step is to etch and simultaneously edge dope the graphene interconnects. For example, the interconnects patterned in FIG. 5D can be etched and doped using a dense N-rich plasma. Immediately after etching, the power on the tool can be cutoff such that pure N-gas blows in the chamber. An Inductively Coupled Plasma (ICP) tool can be used. ICP tools are commonplace in most the prototyping and commercial fabs of most manufacturers. Etching using nitrogen results in the formation of N edge doped graphene interconnects.

As used herein, the term “graphene” can refer to any semiconductor or semimetal that is approaching a 2D (flat sheet) or 1D (nanowire) geometry. As used herein, the phrase “dopant specie” can be any atom, molecule, or structure that chemically or physically bonds or comes into contact with the graphene. As used herein, the term “channel” can refer to a graphene sheet of a specific geometry. This geometry may be formed by etching, cleaving, or simply growing the sheet on a template of the desired geometry.

A graphene channel is provided wherein a significant portion of the carrier density is controlled by the passivation of the edge of the lattice.

A graphene channel is provided wherein the dangling σ-bonds of carbon atoms along the edge of the graphene lattice are passivated with a dopant specie that contributes some significant fraction of positive or negative charge to electrical conduction.

A process for defining a graphene channel is provided wherein chemical doping is applied in the same process step as the physical patterning of the channel.

A process is also provided wherein edge passivation of a graphene channel is applied at the moment or within seconds (e.g., 30 seconds) of the edge being formed.

A process is also provided wherein the dopant specie is physically present at the instant that the edge is formed such that the dopant specie can passivate broken bonds and/or combat lattice reconstructions of the host material.

A nanoscale graphene sheet where chemical doping is applied primarily through interactions with the edge of the graphene (referred to as edge doping) is provided. The graphene sheet is defined as one or two layers of sp2 bound carbon atoms (C-atoms) arranged in a honeycomb lattice. In the case of bilayer graphene, the two layers could be bernal stacked (as with bulk graphite) or rotationally stacked (as with epitaxial graphene grown on SiC). The graphene edge is defined as the carbon atoms (C-atoms) along the edge of the graphene sheet that have a dangling σ-bond as a result of patterning the graphene. This edge could have been formed through lithography and a plasma etch or through mechanical shearing of the graphene. The edge can include C-atoms penetrating at most 2 nm into the center of the graphene sheet. According to some embodiments, the width of the graphene sheet (or minimum dimension) is between 5 nm and 100 nm. The chemical doping is applied to the edge of the graphene sheet via sp2 passivation of the dangling σ-bonds with dopant species. These dopant species can be elements that add (n-type dope) or remove (p-type doping) conducting electrons from the graphene. Exemplary species include, but are not limited to, Nitrogen (N), Hydrogen (H), or Oxygen (O). The majority contributor to the carrier density of the entire graphene sheet is the doping due to passivation of the graphene edge.

The edge doped graphene can be formed through a number of techniques. These techniques fall into two general categories: (1) doping during pattering; and (2) doping after patterning.

Doping during patterning involves combining the patterning of the graphene sheet (i.e., creation of the edge of the channel) and the passivation of the edge within the same process step. At the moment the graphene edge is formed (typically within a window of 30 seconds), C-atoms along the edge are chemically reactive and contain dangling σ-bonds due to the removal of adjacent C-atoms. If the dopant specie is physically present at the edge at the moment the edge is formed and/or the dopant specie provides an energetically favorable alternative to C—C reconstruction of the edge, the edge can be efficiently passivated with the dopant specie. One non-limiting example of how both these criteria can be met is using a nitrogen plasma to etch the graphene. Another non-limiting example is mechanically exfoliating or cleaving graphene sheets in the presence of nitrogen (e.g., in a glovebox purged with nitrogen).

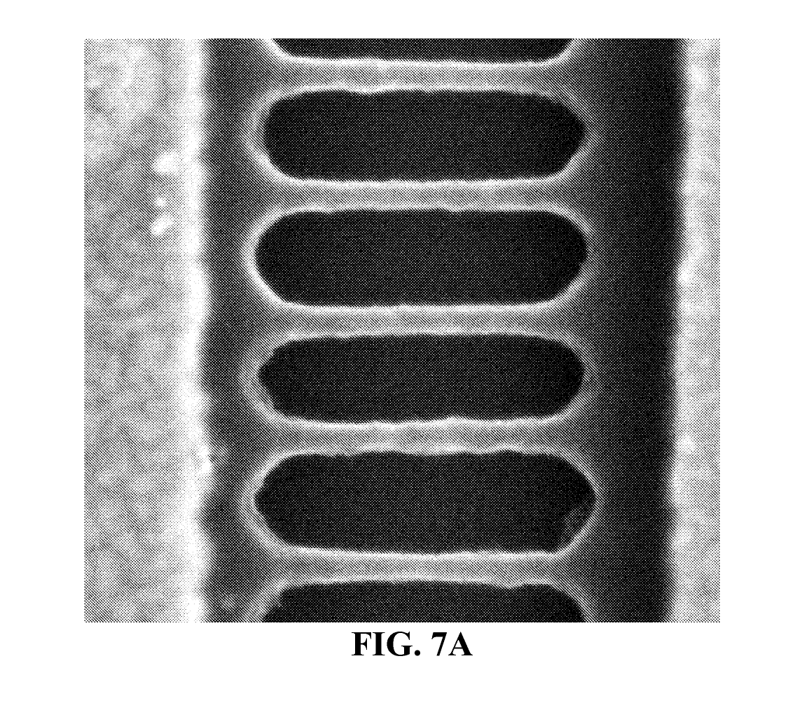

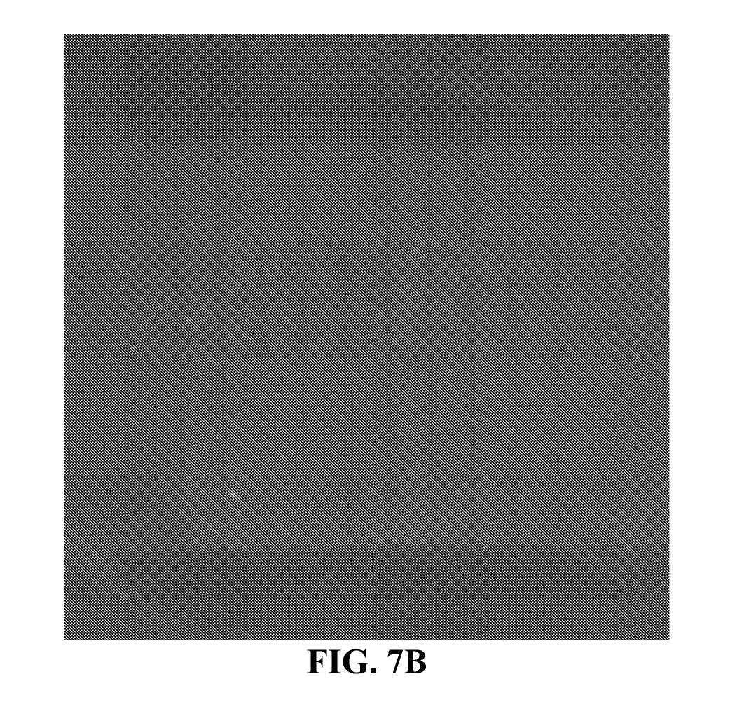

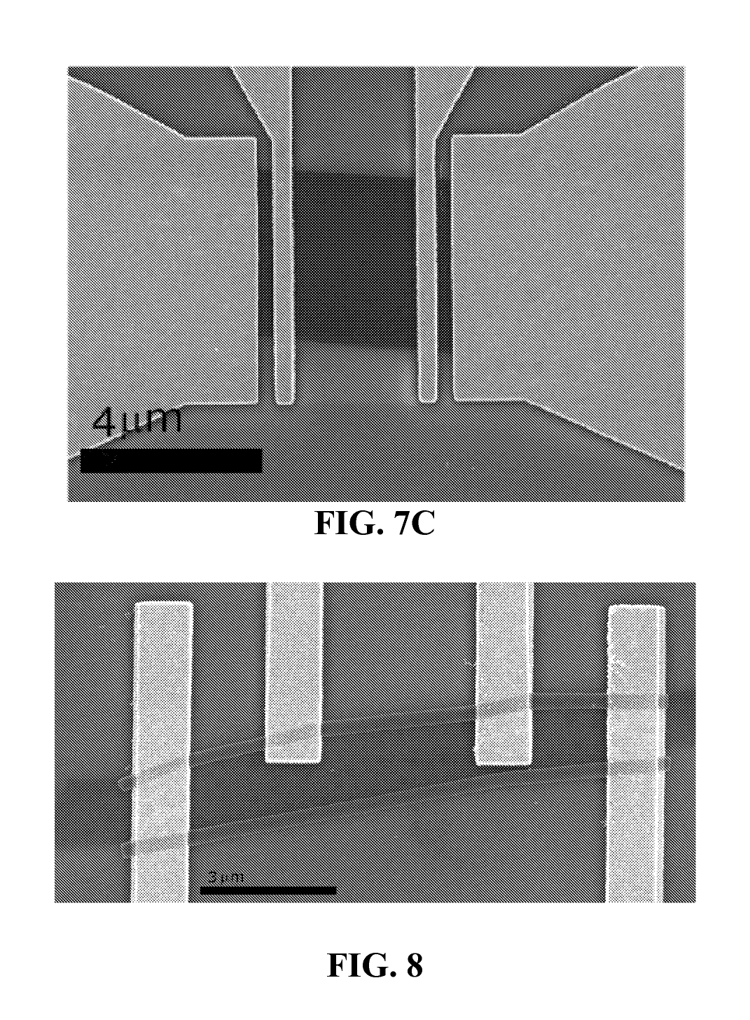

SEM images of graphene sheets that were edge doped in a plasma chamber are shown in FIGS. 7A and 7B. The edge doped graphene interconnects shown in FIGS. 7A and 7B are 20 nm wide. These devices were edge doped in a plasma chamber via plasma of the dopant specie. The device shown in FIG. 7A was made using exfoliated graphene whereas the device shown in FIG. 7B was made using epitaxial graphene.

SEM images of a graphene sheet that was edge doped by mechanical exfoliation in a glovebox purged with the dopant specie are shown in FIG. 7C. The edge doped graphene interconnects shown in FIG. 7C are 3 microns wide.

Doping after patterning involves standard patterning of the graphene, and a follow-on process step of passivating the graphene edge with the dopant specie. One non-limiting example of a method wherein passivation occurs after edge formation is as follows. First a graphene sheet is patterned using a standard lithographic process. Next the edge is physically surrounded by dopant specie. Finally energy is applied to the graphene (possibly in the form of heat or electron-beam irradiation) to displace any existing passivation and replace it with the intended dopant specie. An SEM image of a graphene interconnect that was edge doped in this manner is shown in FIG. 8. The graphene interconnect in FIG. 8 was patterned via mechanical exfoliation. A film of oxygen-rich material was then applied selectively to the edge of the graphene sheet. Once applied, the oxygen rich material was irradiated with electron-beam irradiation to replace the previously doped sites on the graphene edge with oxygen.

Edge doped graphene sheets can find application in various fields. Most of these applications are in the space of nanoscale semiconductor devices. In nanoscale semiconductor devices, edge doping can be used to either (1) increase the carrier density/conductivity or (2) to control the carrier type (i.e., define p-type and n-type regions). Examples of nanoscale semiconductor devices that can benefit from edge doping include local on-chip interconnects, transistors, and memory.

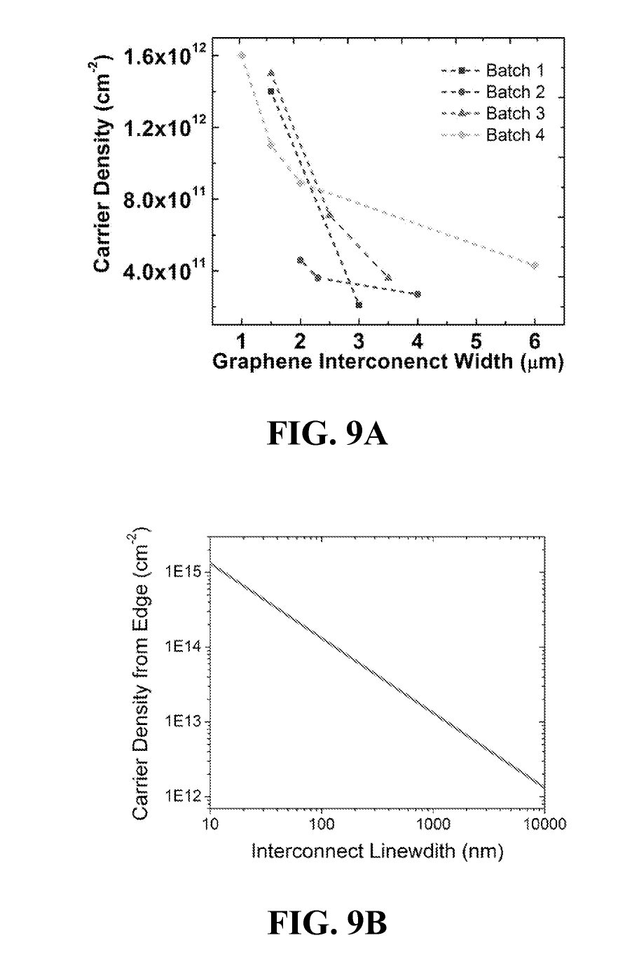

Regarding increasing the electrical conductivity of graphene sheets, edge doped graphene sheets exhibit a valuable scaling trend of increasing carrier density with reduced dimensions. Experimental and theoretical data points of this trend are shown in FIGS. 9A and 9B. This trend results in increased carrier density with reduced physical dimensions and can find application in nanoscale graphene devices. FIG. 9A is a graph of the experimental data showing this trend and FIG. 9B is a graph of the modeling data showing this trend.

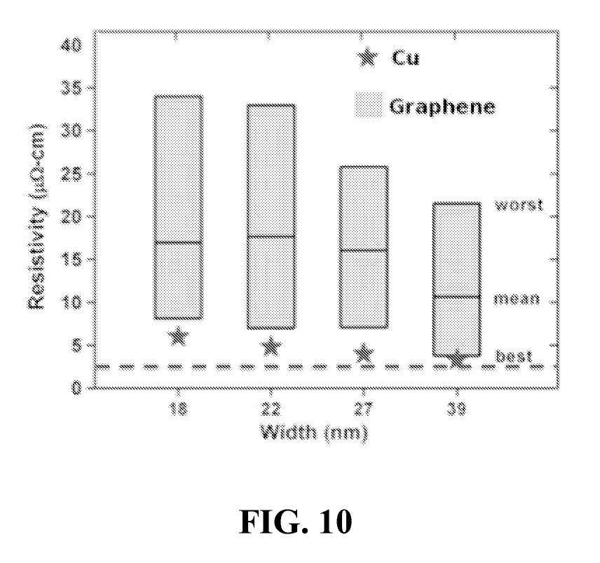

This scaling trend is valuable as larger carrier densities for devices in the 5 nm to 100 nm width will lead to large electrical conductivities. One possible application could be to replace Cu for local on-chip interconnects. Experimental data comparing monolayer edge doped graphene sheets to 1:1 aspect ratio Cu is shown in FIG. 10 which is a bar chart showing resistivity as a function of width (nm) for copper and edge-doped graphene interconnects. As can be seen from FIG. 10, edge doped graphene interconnects having widths of less than 50 nm can have resistivity values comparable to Cu for local interconnect applications.

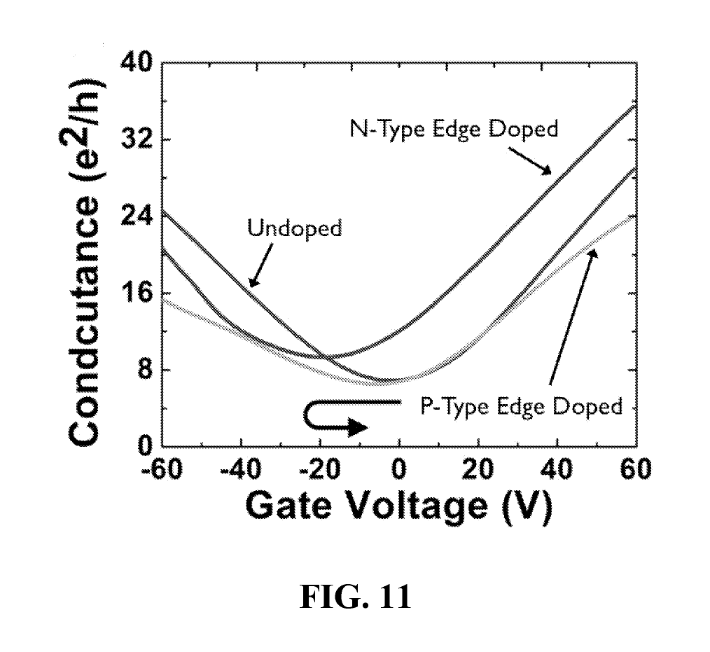

Regarding controlling the carrier type, edge doping can be used to generate n-type and p-type regions of graphene. The formation of these regions (or p-n junctions) is essential to the formation of many semiconductor devices, including transistors, diodes, solar cells, and amplifiers. Experimental data showing the p-type and n-type edge doping of graphene sheets is shown in FIG. 11 which is a graph of conductance as a function of gate voltage for p-type edge doped and n-type edge-doped graphene. As shown in FIG. 11, p-type and n-type graphene can be formed by changing the edge doping specie. The p-type graphene sheet is edge passivated with O and the n-type graphene sheet is edge passivated with H.

Another reason edge doped graphene is valuable for nanoscale semiconductor devices is that if chemical doping can be applied only through passivation of the edge, the center of the material can remain pristine. Doping while maintaining pristine material in the center can have many advantages for maintaining high carrier mobility or functionality of the graphene (e.g., mechanical, thermal, etc).

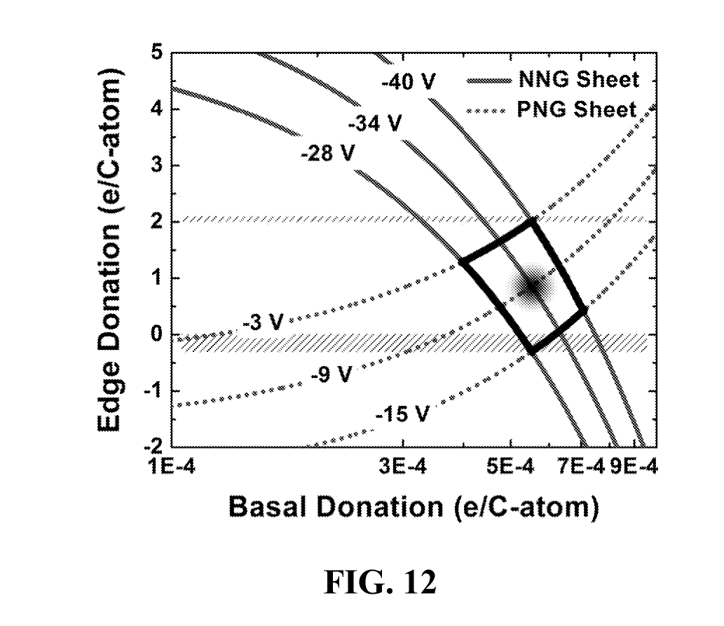

Edge doped graphene and the function of edge passivation of graphene sheets to control the carrier density is non-trivial and unique for a number of reasons. First and foremost, it would not have been expected that the small fraction of C-atoms within the graphene sheet (i.e., those residing on the edge alone) can actually control the overall carrier density of the entire graphene sheet. Unlike surface passivation with nanowires and other bulk materials (i.e., Si, GaN, InP, GaAs), graphene is a 2D material with only two surfaces—the edge and the basal plane. It has been experimentally shown that there is a very large mismatch between the doping potential of a C-atom on the edge of the graphene sheet and in the basal plane (center) of the graphene sheet. As such, passivating the edge C-atoms alone is capable of entirely controlling the carrier density and even overwhelming the contribution from all basal plane C-atoms. This work is shown in FIG. 12 which is a graph of experimental data showing that C-atoms in the graphene sheet along the edge are orders of magnitude more efficient for chemical doping than C-atoms in the surface/basal plane of the material.

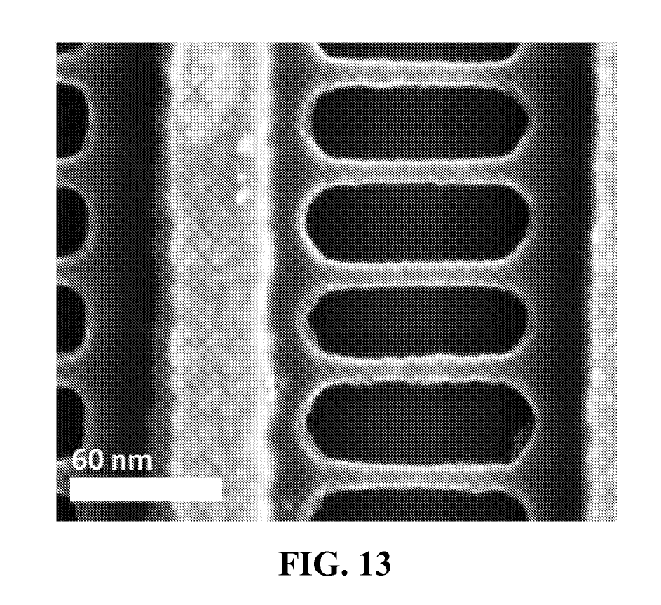

Three different elements have been used to passivate the graphene edge: oxygen (O), nitrogen (N), and hydrogen (H). A plasma was used to apply the 0-passivation and N-passivation. The terms “passivation” and “doping” can be used interchangeably. An SEM image of a nanoscale (20 nm width) graphene interconnect with edge doping applied during the plasma etch is shown in FIG. 13.

FIG. 13 is an SEM image of 20 nm wide graphene interconnects with p-type edge doping applied during etching with an O₂ plasma. The p-type edge doping is a result of sp2 O-passivation along the graphene edge. An etch mask is visible atop the graphene and is used to pattern the interconnect.

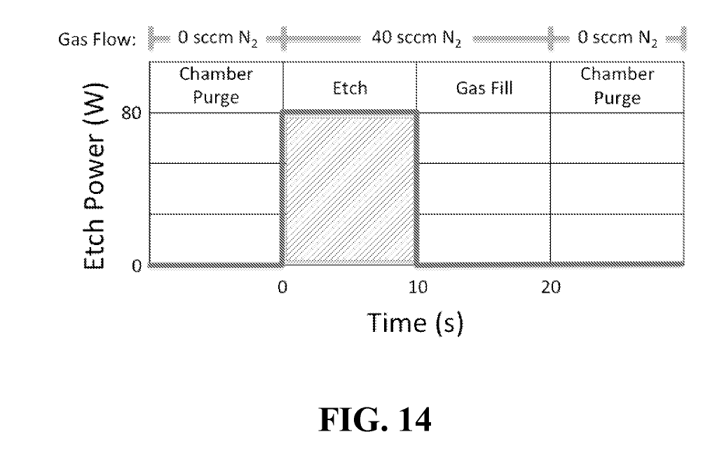

To apply edge doping using a plasma, we have used both an Reactive Ion Etch (RIE) tool and an Inductively Coupled Plasma (ICP) tool. A typical (non-limiting) etch recipe would consist of two stages. These two stages are shown in FIG. 14. FIG. 14 is a schematic showing an edge doping recipe implemented on an ICP tool. The chamber is under vacuum from a rough pump and in the range of 90 mTorr. As shown in FIG. 14, the first stage physically etches the graphene by igniting a plasma of the edge doping specie (e.g., N₂ gas). The second stage extinguishes the plasma by cutting the etching power and fills the chamber with the gaseous doping specie. This allows the freshly cleaved edge to be passivated.

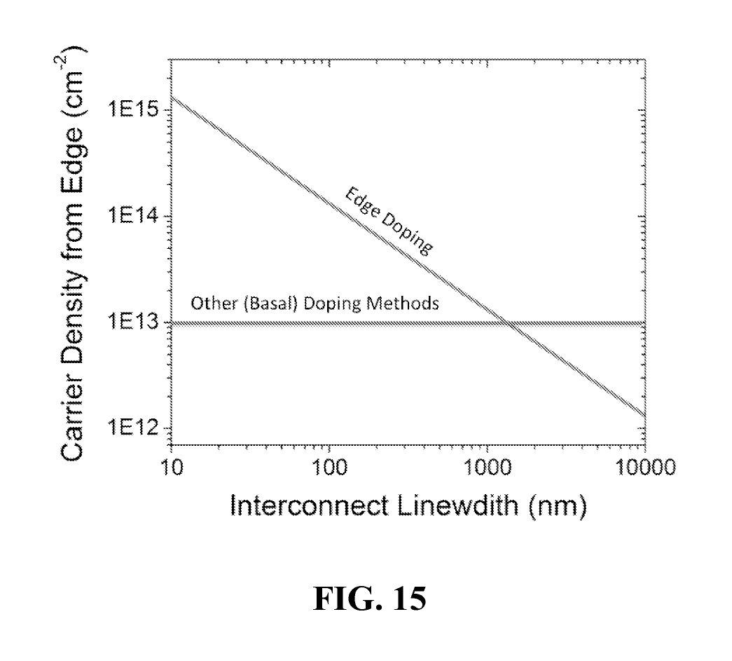

Edge doped graphene interconnects have been fabricated in a width range from 1 to 10 μm. At widths below 1 μm, edge doping becomes valuable to the formation of graphene interconnects. The reason for this is as follows. When edge doping, the carrier density of the interconnect becomes larger as the width is reduced (i.e., the same number of carrier are injected from the edge, yet the area of the interconnect decreases). A model-based extrapolation of the edge doping carrier density is shown in FIG. 15. FIG. 15 is a graph of carrier density versus the width of a graphene interconnects. In FIG. 15, edge doped interconnects are compared against other (basal) doping methods. As shown in FIG. 15, below a 1 μm width, edge doping is projected to produce larger carrier densities than those possible through interactions with the graphene surface. Doping graphene using other methods (i.e., interactions with surface/basal plane of the graphene sheet) typically only result in carrier densities as high as 3×10¹² cm⁻². As a result, at graphene interconnect widths below 1 μm, edge doping provides a larger carrier density than most other doping methods.

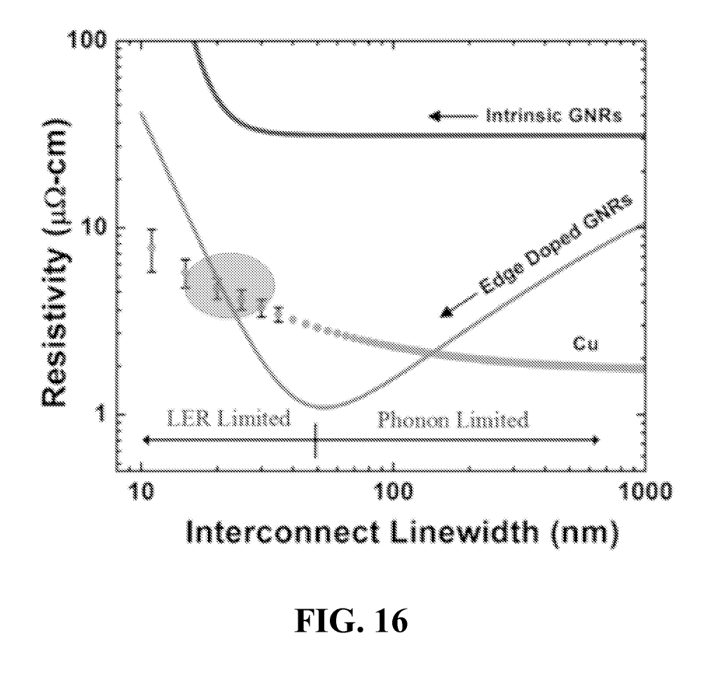

The value of edge doping is further demonstrated by comparing the resistivity of three interconnects: Cu (the current material in CMOS chips), edge doped graphene, and basal doped graphene. This is shown in FIG. 16 which is a plot of resistivity as a function of interconnect width for three different interconnects: Cu, edge doped graphene, and basal doped graphene. The shaded oval region indicates the area of actual devices that have been fabricated. This region corresponds to edge doping carrier densities in the range of 10¹⁴ to 10¹⁵ cm⁻². Carrier density was determined by back calculating from resistivity using the interconnect width and line edge roughness. This indicates that edge doped carrier densities on the order of 10¹⁴ to 10¹⁵ cm⁻² have been achieved in nanoscale graphene interconnects. As shown in FIG. 16, edge doped graphene interconnects exhibit a much lower resistivity than intrinsic (basal doped) graphene interconnects. Edge doping also allows the resistivity of graphene to become comparable to that of Cu. The red circle is the region where edge doped interconnects have been fabricated.

One non-limiting application of Edge Doping is to combat the onset of edge scattering in nanoscale graphene interconnects, allowing them to perform comparable to Cu in regards to RC delay and energy delay product.

As graphene sheets are etched or patterned into nanoscale channels, the roughness along the edge becomes a leading source of scattering for mobile charge. As such, as the width of a graphene interconnect is shrunk below 100 nm, this Line-Edge-Roughness (LER) scattering rapidly increases the resistivity of the interconnect. Specifically, this increase in resistivity is exponential and would normally render the resistivity of graphene one or two orders of magnitude above copper (Cu) interconnects at a similar width. In short, a graphene interconnect subject to LER is not viable as a replacement to Cu interconnects in the nanoscale.

LER is a result of physical roughness along the edge of the graphene interconnect. This roughness stems from a combination of the roughness of the etch mask/resist used to the pattern the interconnect, as well as the etching process (e.g., plasma etching). Removing LER from graphene interconnects would require tremendous advances in patterning/etching, the formation of atomically smooth edges, and is completely beyond the scope of current semiconductor processing capabilities. As such, graphene interconnects are unavoidably dominated by LER at widths below 100 nm and are not viable as a replacement technology to Cu. As used herein, the line edge roughness (LER) of an interconnect is the distance between the widest and narrowest portion of the interconnect. Edge doping is particularly beneficial when the LER of the graphene interconnect is comparable or larger than the Fermi wavelength of graphene which is approximately 1 nm. According to some embodiments, the edge doped graphene interconnects have am LER of 0.2 nm or more. According to some embodiments, the edge doped graphene interconnects have am LER of 0.5 nm or more.

The use of edge doping mitigates the effects of LER by balancing a reduction in carrier mobility (i.e., edge scattering) with an increase in carrier density (i.e., chemical doping). Traditional methods of chemical doping graphene are only capable of raising the carrier density to a value on the order of 5×10¹² cm⁻². This carrier density is not high enough to mitigate LER and make graphene viable as a replacement to Cu interconnects in the nanoscale (e.g., <100 nm linewidth). The present invention (Edge Doping) is capable of raising the carrier density to an order of 5×10¹²-10¹⁵ cm⁻². These carrier densities are not possible through other traditional doping techniques and are necessary for making graphene comparable to Cu interconnects in regards to resistance per unit length, RC delay and energy delay product.

The use of edge doping allows graphene to become comparable to Cu in with respect to resistance per unit length, RC delay and energy delay product. As a result, graphene becomes viable as a replacement for Cu given its other benefits. That is, if graphene can be made comparable (or improved) to Cu regarding RC Delay and Energy Delay Product, it can be integrated to maintain the status quo with regard to these properties but receive other peripheral benefits that are instinct to graphene. These other benefits include eased processing (top-down lithography instead of trench filling), larger current carrying capacities (avoiding electromigration failures of Cu), and lower dynamic power dissipation (due to graphene being flat over 2:1 aspect ratio Cu). The definition of “comparable” will be known to those skilled in the art and is specific to the particular end chipset and/or application of the chip.

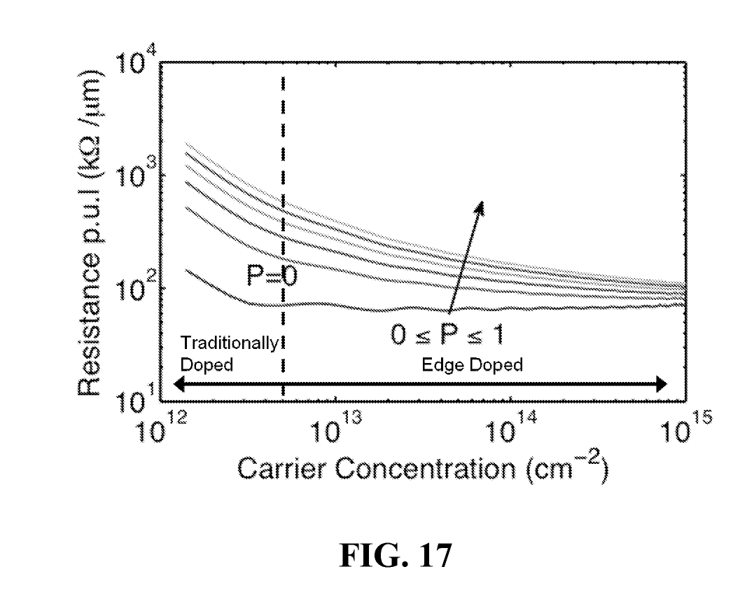

FIGS. 17-19 were generated by models based off of experimental data points. The “degree” of LER scattering is captured through the edge's backscattering probability, P. At P=0 the interconnect has perfectly smooth edges (atomically smooth edges) and no scattering. At P=1 we have an interconnect with edges that scatter 100% of the carriers (very rough edges). Actual fabricated devices currently fall in the range of about P=0.7. It can be seen that as the carrier density approaches 10¹⁵ cm⁻², the curves for various P values start to merge and LER becomes mitigated.

FIG. 17 is a graph showing resistance as a function of carrier concentration for graphene interconnects having different P-values. The interconnects used in FIG. 17 have a linewidth of 7.5 nm. The extent of LER is captured using a backscattering probability (P) that is swept between 0 and 1. Current manufacturing yields P˜0.7. As shown in FIG. 17, edge doping reduces the resistance per unit length of the graphene interconnects.

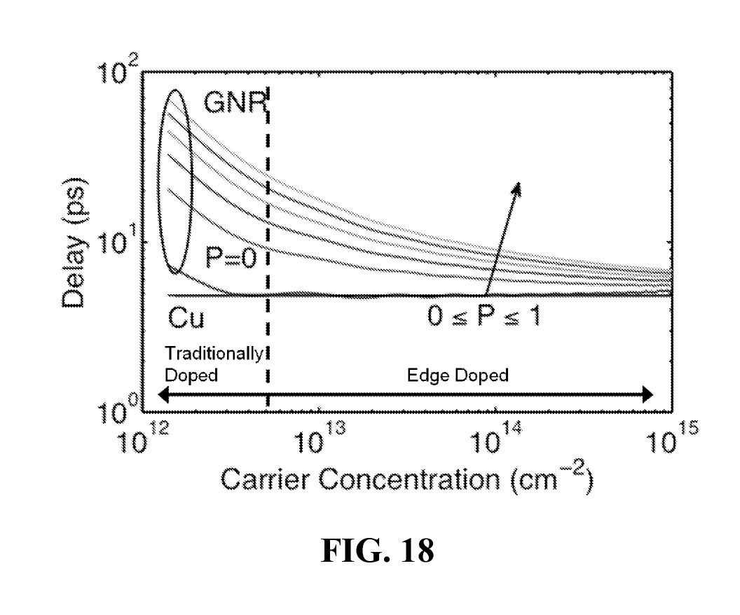

FIG. 18 is a graph of delay as a function of carrier concentration for graphene interconnects having different P-values. The interconnects used in FIG. 17 have a linewidth of 7.5 nm. The extent of LER is swept from a backscattering probability (P) of 0 to 1. Current manufacturing yields P˜0.7. As shown in FIG. 18, edge doping of the graphene brings the delay of graphene down to levels comparable to Cu.

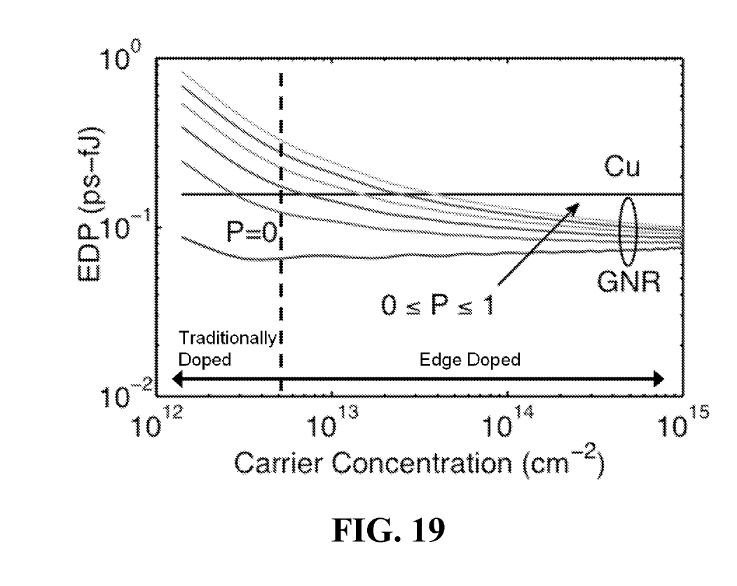

FIG. 19 is a graph of energy delay product (EDP) as a function of carrier concentration for graphene interconnects having different P-values. The interconnects used in FIG. 19 have a linewidth of 7.5 nm. The extent of LER is swept from a backscattering probability (P) of 0 to 1. Current manufacturing yields P˜0.7. As shown in FIG. 19, edge doping brings the energy delay product of graphene down to levels below (i.e., superior to) Cu.

The following table shows the percentage improvements in resistance per unit length of a graphene interconnect with edge doping at various widths and P values. Graphene interconnects without edge doping have a carrier density of 5×10¹² and graphene interconnects with edge doping have a carrier density of 1×10¹⁴.

| | P = 0.6 | | | P = 1.0 | | |
|---|---|---|---|---|---|---|
| Width | r (kΩ/μm) | | % | r (kΩ/μm) | | % |
| (nm) | n = 5e12 cm⁻² | n = 1e14 cm⁻² | Change | n = 5e12 cm⁻² | n = 1e14 cm⁻² | Change |
| 180 | 3.81 | 2.932 | 23 | 4.2 | 3 | 29 |
| 42 | 23.57 | 14.66 | 38 | 28.74 | 16.2 | 44 |
| 21 | 63.46 | 33.84 | 47 | 82.81 | 39.1 | 53 |
| 15 | 108.2 | 51.94 | 52 | 147.8 | 61.48 | 58 |
| 7.5 | 391.4 | 132.5 | 66 | 595.2 | 165.7 | 72 |

While the foregoing specification teaches the principles of the present invention, with examples provided for the purpose of illustration, it will be appreciated by one skilled in the art from reading this disclosure that various changes in form and detail can be made without departing from the true scope of the invention.

### REFERENCES

[1] X. Wang et al., “N-Doping of Graphene through Electrochemical Reactions with Ammonia,” Science (2009).
[2] H. Lim et al., “Spontaneous Reactivity of Diazonium Salt on Edge and Basal Plane of Graphene without Surfactant and its Doping Effect,” Langmuir (2010).
[3] Y. Lin, “Controllable Graphene N-Doping with Ammonia Plasma,” Applied Physics Letters (2012).

1. (canceled)

2. The article of manufacture of claim 12, wherein selective removal comprises etching or mechanical exfoliation.

3. The article of manufacture of claim 12, wherein nitrogen is the dopant and wherein selective removal comprises etching with a nitrogen plasma.

4. (canceled)

5. The article of manufacture of claim 12, wherein the substrate is a dielectric material or SiO₂.

6. (canceled)

7. The article of manufacture of claim 12, wherein the dopant is selected from the group consisting of nitrogen, oxygen and hydrogen.

8. The article of manufacture of claim 12, wherein the graphene channels have a width of less than 1 μm.

9. The article of manufacture of claim 12, wherein the one or more graphene channels are p-type doped or n-type doped.

10. The article of manufacture of claim 12, further comprising exposing the graphene to the dopant after formation of the graphene channels.

11. (canceled)

12. An article of manufacture made by a method comprising:
forming one or more graphene channels having edges by selectively removing graphene from a graphene layer, wherein the graphene layer is on a substrate and wherein formation of the graphene channels occurs in the presence of a dopant;
wherein atoms of the dopant form bonds with carbon atoms on the edge of the graphene such that the one or more graphene channels are edge doped.

13. The article of manufacture of claim 12, wherein each of the one or more the graphene channels has a width less than 1 μm and a carrier density greater than 10¹³ cm⁻³.

14. The article of manufacture of claim 12, wherein each of the one or more the graphene channels has a width less than 1 μm and a carrier density of at least 10¹⁴ cm⁻³.

15-17. (canceled)

18. An article of manufacture comprising:
a substrate layer;
one or more graphene channels on the substrate layer, wherein the graphene channels have edges and wherein atoms of a dopant form bonds with carbon atoms on the edges of the one or more graphene channels; and
a layer of an etch mask material on and coextensive with the one or more graphene channels.

19. The article of manufacture of claim 18, wherein the dopant is selected from the group consisting of nitrogen, oxygen and hydrogen.

20. The article of manufacture of claim 18, wherein each of the one or more the graphene channels has a width less than 1 μm and a carrier density greater than 10¹³ cm⁻³.

21. The article of manufacture of claim 18, wherein each of the one or more the graphene channels has a width less than 1 μm and a carrier density of at least 10¹⁴ cm⁻³.

22. The article of manufacture of claim 18, wherein the substrate is a dielectric material or SiO₂.

23. (canceled)

24. An article of manufacture comprising:
a substrate layer;
one or more graphene channels on the substrate layer, wherein the graphene channels have edges and wherein atoms of a dopant forms bonds with carbon atoms on the edges of the one or more graphene channels;
wherein the one or more the graphene channels has a width less than 100 nm and a carrier density greater than 5×10¹² cm⁻³.

25. The article of manufacture of claim 24, wherein the dopant is selected from the group consisting of nitrogen, oxygen and hydrogen.

26. The article of manufacture of claim 24, wherein each of the one or more the graphene channels has a carrier density of at least 1×10¹³ cm⁻³ or at least 1×10¹⁴ cm⁻³.

27. The article of manufacture of claim 24, wherein the substrate layer is a dielectric material or SiO₂.

28. (canceled)

29. The article of manufacture of claim 24, wherein the one or more graphene channels have a line edge roughness (LER) of at least 0.2.

30. The article of manufacture of claim 24, wherein the one or more the graphene channels have a width less than 50 nm or a width less than 10 nm.
